(19) United States
(12) Patent Application Publication
(10) Pub. No.: US 2008/0290454 A1
(43) Pub. Date: Nov. 27, 2008

(54) SEMICONDUCTOR INTEGRATED CIRCUIT DEVICE AND METHOD FOR MANUFACTURING THE SAME

(75) Inventor: Shinji Fujii, Yokohama-shi (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 12/025,311

(22) Filed: Feb. 4, 2008

(30) Foreign Application Priority Data
Feb. 20, 2007 (JP) 2007-039157

(51) Int. Cl. H01L 23/52; H01L 21/4763

(52) U.S. Cl. 257/529; 257/532; 438/622; 257/E23.141; 257/E21.495

(57) ABSTRACT

A semiconductor integrated circuit device includes a plurality of metal wirings which are separated from one another with respective interlayer insulating films; at least one interlayer conductor for connecting adjacent ones of the metal wirings via the corresponding one of the interlayer insulating films; at least one functional element formed above a semiconductor substrate and between adjacent ones of the interlayer insulating films; and at least one dummy metal portion which is formed above and/or below the functional element via at least one of the interlayer insulating films so as to be located inside the at least one interlayer conductor.

### CROSS-REFERENCE TO RELATED APPLICATIONS

This application is based upon and claims the benefit of priority from the prior Japanese Patent Application No. 2007-039157 filed on Feb. 20, 2007; the entire contents which are incorporated herein by reference.

### BACKGROUND OF THE INVENTION

1. Field of the Invention

The present invention relates to a semiconductor integrated circuit device including a functional element and a method for manufacturing the semiconductor integrated circuit device.

2. Description of the Related Art

With the development of the downsizing of a semiconductor integrated circuit, an interlayer insulating film to separate adjacent wiring layers in insulation is likely to be made of a material with a low dielectric constant so as to reduce the parasitic capacitance between the adjacent wiring layers. In the thermal process after trenches are formed in the interlayer insulating film such that the wiring layers are formed in the trenches, gas components and moisture component remaining in the interlayer insulating film are emitted from the trenches before the wiring layers are formed in the trenches.

As described above, if the interlayer insulating film is made of the low dielectric constant material, the mechanical properties such as stiffness of the resultant semiconductor integrated circuit substrate may be deteriorated because the stiffness of the low dielectric constant material is normally low. In the case that the trenches for forming the wiring layers are formed, if openings (vias) are formed so as to form the interlayer connectors continuous to the trenches, the gas components and the moisture component are emitted from some of the trenches as described above so as to be concentrated on and thus, damaged for the openings when other trenches are not almost formed around the intended trenches. As a result, the resistances of the openings are increased so that the electric characteristics of the semiconductor integrated circuit device are deteriorated.

In this point of view, with the semiconductor integrated circuit as described above, some dummy metal patterns would be formed on the areas in which the wiring layers are not formed in the interlayer insulating film. In this case, the deterioration in stiffness of the semiconductor integrated circuit device due to the use of the low dielectric constant material can be suppressed. Also, the concentration of the gas components and moisture component from the interlayer insulating film for the openings (vias) continuous to the trenches for forming the wiring layers can be suppressed. Such a restriction as described above is normally called as a “metal covering ratio rule restriction”. Particularly, such an attempt as positively forming the dummy metal pattern in the nondense area of the wiring layer is made in Reference 1.

[Reference 1] JP-A 04-307958 (KOKAI)

In the case that the semiconductor integrated circuit device includes a functional element such as a capacitance element, if the dummy metal patterns are formed, the parasitic capacitances are generated between the capacitance element and the dummy metal patterns so that the capacitance element can not exhibit the inherent performance. In the case that the semiconductor integrated circuit device includes a functional element such as a metal fuse, if the dummy metal patterns are formed, the laser beam is attracted to the dummy metal patterns in the process of cutting the metal fuse with the laser beam. Therefore, the blow margin can not be obtained sufficiently so that the laser beam can not be sufficiently irradiated onto the metal fuse and thus, the above-described cutting process can not be performed sufficiently.

### BRIEF SUMMARY OF THE INVENTION

An aspect of the present invention relates to a semiconductor integrated circuit device, including: a plurality of metal wirings which are separated from one another with respective interlayer insulating films; at least one interlayer conductor for electrically connecting adjacent ones of the metal wirings through the corresponding one of the interlayer insulating films; at least one functional element formed above a semiconductor substrate and between adjacent ones of the interlayer insulating films; and at least one dummy metal portion which is formed above and/or below the functional element at least one of the interlayer insulating films so as to be located inside the at least one interlayer conductor.

Another aspect of the present invention relates to a method for manufacturing a semiconductor integrated circuit device, including: forming a first metal wiring above a semiconductor substrate; forming a first interlayer insulating film on the first metal wiring; forming a first trench and a second trench in the first interlayer insulating film so that the second trench is located outside the first trench; forming a dummy metal portion in the first trench; forming a second metal wiring in the second trench; forming an interlayer conductor for electrically connecting the first metal wiring and the second metal wiring through the first interlayer insulating film; forming a second interlayer insulating film on the first interlayer insulating film so as to cover the dummy metal portion and the second metal wiring; and forming a functional element in the second interlayer insulating film.

### BRIEF DESCRIPTION OF THE DRAWINGS

FIG. 1 is a plan view schematically showing a semiconductor integrated circuit device according to a first embodiment.

FIG. 2 is a cross sectional view of the semiconductor integrated circuit device shown in FIG. 1, taken on line I-I.

FIG. 3 is a plan view schematically showing a semiconductor integrated circuit device modified from the one of the first embodiment.

FIG. 4 is a cross sectional view schematically showing another semiconductor integrated circuit device modified from the one of the first embodiment.

FIG. 5 is a plan view schematically showing a semiconductor integrated circuit device according to a second embodiment.

FIG. 6 is a cross sectional view of the semiconductor integrated circuit device shown in FIG. 5, taken on line II-II.

### DETAILED DESCRIPTION OF THE INVENTION

Then, some embodiments will be described with reference to the drawings.

### First Embodiment

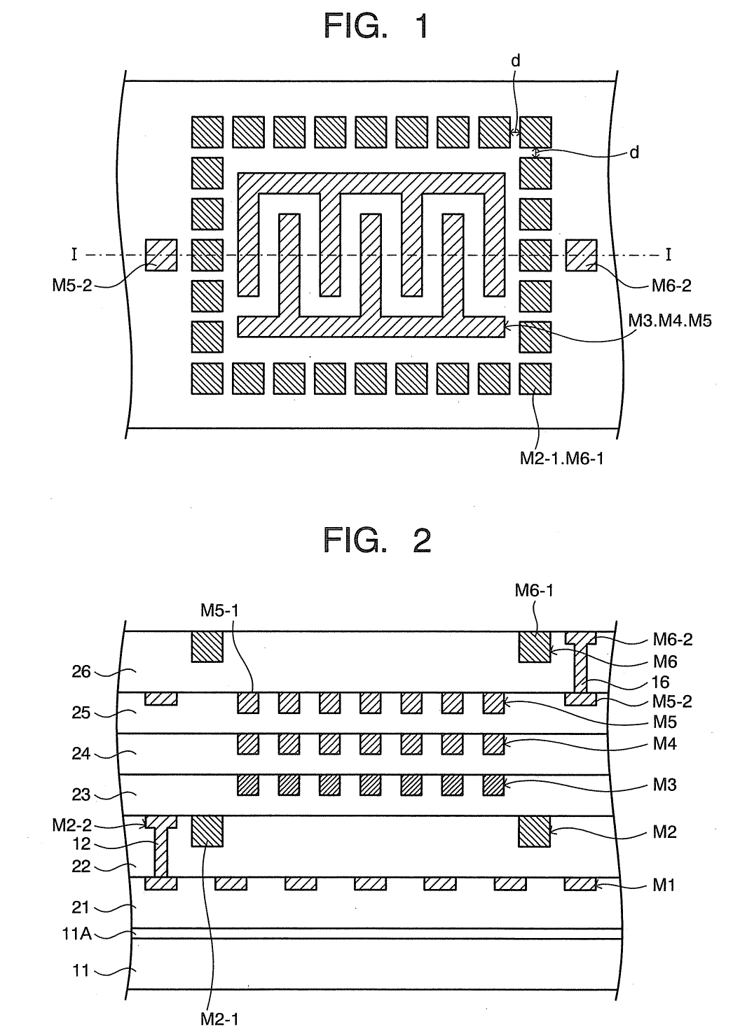

FIG. 1 is a plan view schematically showing a semiconductor integrated circuit device according to a first embodiment. FIG. 2 is a cross sectional view of the semiconductor integrated circuit device shown in FIG. 1, taken on line I-I. For clarifying the distinctive feature of the present embodiment, some components may be different from the real ones in size and the like.

In the semiconductor integrated circuit device 10 shown in FIGS. 1 and 2, a first interlayer insulating film 21 and a first metal layer M1; a second insulating film 22 and a second metal layer M2; a third insulating film 23 and a third metal layer M3; a fourth insulating film 24 and a fourth metal layer M4; a fifth insulating film 25 and a fifth metal layer M5; and a sixth insulating film 26 and a sixth metal layer M6 are subsequently formed on a semiconductor substrate 11 made of, e.g., silicon via an element separating area 11A which is formed at the surface area of the semiconductor substrate 11.

The first metal pattern M1 constitutes a wiring pattern and the second metal layer M2 constitutes a dummy metal portion M2-1 and a wiring pattern M2-2. The third metal layer M3 and the fourth metal layer M4 constitute capacitance elements (functional elements), respectively. The fifth metal layer M5 constitutes a capacitance element (functional element) M5-1 and a wiring pattern M5-2. The sixth metal layer M6 constitutes a dummy metal portion M6-1 and a wiring pattern M6-2.

The first metal layer M1 is electrically connected with the wiring pattern M2-2 of the second metal layer M2 with an interlayer connector (via) 12. The sixth metal layer M6 is electrically connected with the wiring pattern M5-2 of the fifth metal layer M5 with an interlayer connector (via) 16. In this case, wiring patterns for the third metal layers M3 and the fourth metal layer M4 are omitted.

In this embodiment, as viewed in the lateral direction of the semiconductor integrated circuit device 10 shown in FIGS. 1 and 2, the second metal layer M2 and the sixth metal layer M6 includes the dummy metal portion M2-1 and M6-1 which are located inside the interlayer connectors 12, 16 and outside the metal layers M3, M4, M5 (capacitance element M3, M4, M5-1). Then, as apparent from FIG. 1, the dummy metal portions M2-1 and M6-1 are made of a plurality of metal pieces so that the metal pieces enclose the metal layers M3, M4, M5 by a spacing “d”.

During the manufacture of the semiconductor integrated circuit device shown in FIGS. 1 and 2, therefore, even though the second interlayer insulating film 22 is formed after the first interlayer insulating film 21 and the first metal layer M1 are formed and thermal treatment is conducted for the second interlayer insulating film 22 before the second metal layer M2 is formed, the gas components and moisture component remaining in the second interlayer insulating film 22 are concentrated on the trench (dummy trench) which is previously formed so as to form the dummy metal portion M2-1 and thus, emitted outside via the trench, not the trench (wiring trench) which is previously formed so as to form the wiring pattern M2-2.

As a result, the gas components and moisture component are not concentrated on the trench for forming the wiring pattern M2-2 so that the damage of the opening for forming the interlayer connector 12, the opening being continuous to the trench, can be suppressed and thus, the increase in resistance of the opening can be suppressed.

Even though the third interlayer insulating film 23 and the third metal layer M3; the fourth interlayer insulating film 24 and the fourth metal layer M4; the fifth interlayer insulating film 25 and the fifth metal layer M5; and the sixth interlayer insulating film 26 are subsequently formed and thermal treatment is conducted for the sixth interlayer insulating film 26 before the sixth metal layer M6 is formed, the gas components and moisture component remaining in the sixth interlayer insulating film 26 are concentrated on the trench (dummy trench) which is previously formed so as to form the dummy metal portion M6-1 and thus, emitted outside via the trench, not the trench (wiring trench) which is previously formed so as to form the wiring pattern M6-2.

As a result, the gas components and moisture component are not concentrated on the trench for forming the wiring pattern M6-2 so that the damage of the opening for forming the interlayer connector 16, the opening being continuous to the trench, can be suppressed and thus, the increase in resistance of the opening can be suppressed.

Accordingly, the increase in resistance of the openings for forming the interlayer connectors 12 and 16 can be suppressed so that the deterioration of the electric characteristics of the semiconductor integrated circuit device 10 can be prevented.

Moreover, since the dummy metal portions M2-1 and M6-1 are formed so as to enclose the metal layers M3, M4 and M5 (capacitance elements M3, M4 and M5-1), the stiffness of the interlayer insulating films 21 to 26 can be compensated with the dummy metal portions M2-1 and M6-1 even though the interlayer insulating films 21 to 26 are made of low dielectric material with low stiffness. As a result, the mechanical strength of the semiconductor integrated circuit device 10 can be maintained sufficiently in the use of the low dielectric material.

Moreover, since the dummy metal portions M2-1 and M6-1 are not superimposed vertically with the metal layers M3, M4 and M5 (capacitance elements M3, M4 and M5-1), no parasitic capacitance is generated between the dummy metal portions M2-1, M6-1 and the metal layers M3, M4, M5. As a result, the electric characteristics of the semiconductor integrated circuit device 10 can be set as designed and thus, not shifted from the initial design.

In this embodiment, the dummy metal portions M2-1 and M6-1 are made of the metal pieces as described above. In this case, the spacing “d” between the adjacent pieces is set three times or less as large as the minimum wiring spacing required for the semiconductor integrated circuit device. Preferably, the spacing “d” is set to the minimum wiring spacing or less. In this case, the gas components and moisture component remaining in the interlayer insulating films 21 and 26 are not captured in and thus, passed through the trenches for forming the dummy metal portions M2-1 and M6-1. Therefore, the gas components and moisture component are unlikely to be delivered to the trenches for forming the wiring patterns M2-2 and M6-2.

The minimum wiring spacing is required for a semiconductor integrated circuit device by generation, and reduced with the development of the downsizing the semiconductor integrated circuit device. The present semiconductor integrated circuit device is called as a “65 nm generation” so that the minimum wiring spacing is set to 0.1 μm. The minimum wiring spacing is also called as a “minimum spacing rule”.

The metal layers M1 to M6 partially constitute the wiring pattern as described above. In this point of view, the metal layers M1 to M6 may be made of a conventional wiring pattern material such as Cu, Au, Ag, Al.

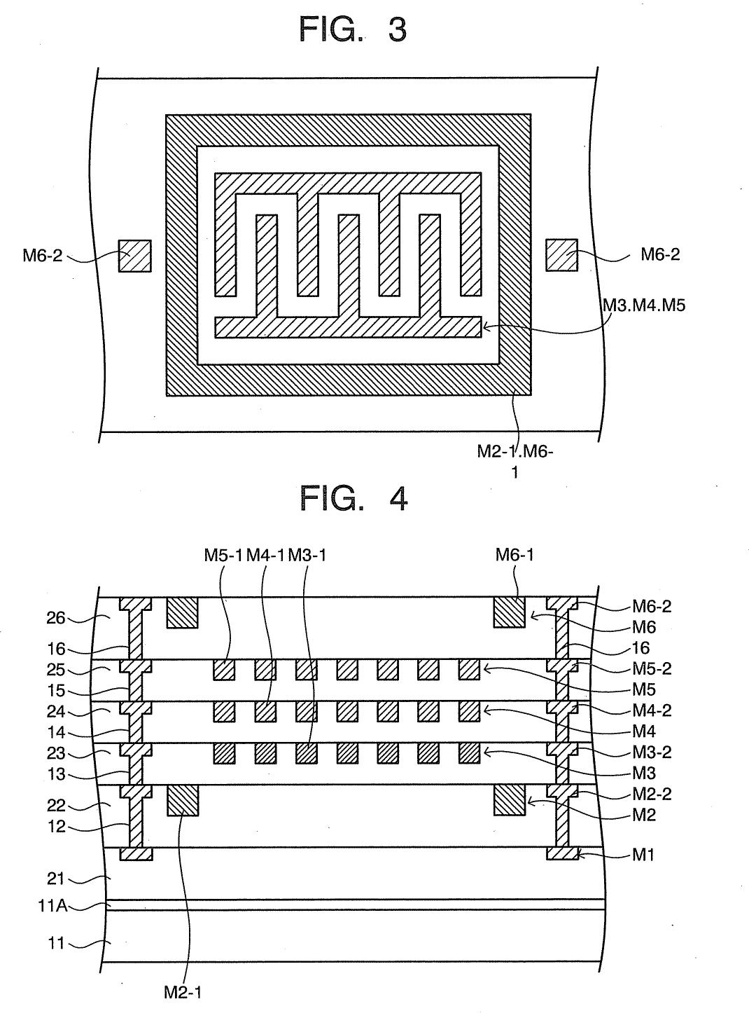

FIG. 3 is a plan view schematically showing a semiconductor integrated circuit device modified from the one of the first embodiment. In the first embodiment, the dummy metal portions M2-1 and M6-1 are made of the metal pieces, but in this modified embodiment, the dummy metal portions M2-1 and M6-1 are made of continuous metal members, respectively. Therefore, since the trenches for forming the dummy metal portions are continuous so that the gas components and moisture component are not captured in and thus, passed through the trenches. As a result, the gas components and moisture component are unlikely to be delivered to the trenches for forming the wiring patterns M2-2 and M6-2.

In this embodiment, the cross section of the semiconductor integrated circuit device is similar to the one related to the first embodiment.

FIG. 4 is a cross sectional view schematically showing another semiconductor integrated circuit device modified from the one of the first embodiment. In the first embodiment, the second metal layer M2, the fifth metal layer M5 and the sixth metal layer M6 include the wiring patterns M2-2, M5-2 and M6-2, respectively, but in this modified embodiment, the third metal layer M3 and the fourth metal layer M4 also includes the wiring patterns M3-2 and M4-2.

In this embodiment, the gas components and moisture component remaining in the third interlayer insulating film 23, the fourth interlayer insulating film 24, the fifth interlayer insulating film 25 and the sixth interlayer insulating film 26 are concentrated on the trench (dummy trench) which is previously formed so as to form the dummy metal portion M6-1 and thus, emitted outside via the trench, not the trench (wiring trench) which is previously formed so as to form the wiring pattern M6-2. As a result, the gas components and moisture component are not concentrated on the trench for forming the wiring pattern M6-2 so that the damage of the opening for forming the interlayer connector 16, the opening being continuous to the trench, can be suppressed and thus, the increase in resistance of the opening can be suppressed. Accordingly, the deterioration of the electric characteristics of the semiconductor integrated circuit device 10 can be prevented.

### Second Embodiment

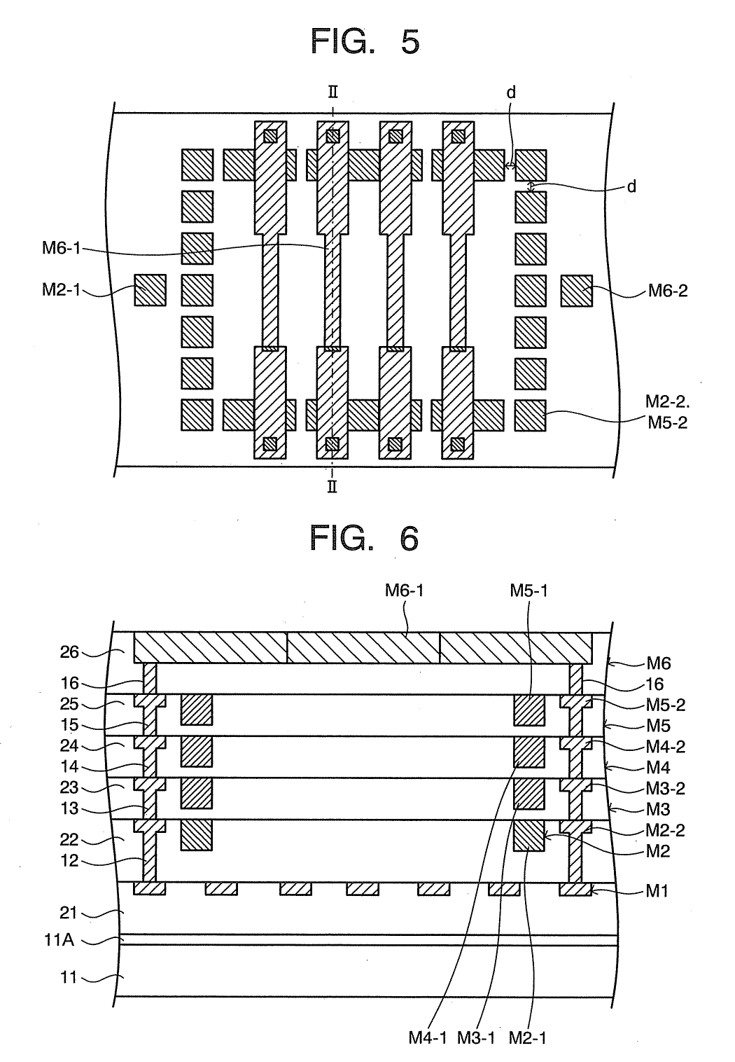

FIG. 5 is a plan view schematically showing a semiconductor integrated circuit device according to a second embodiment. FIG. 6 is a cross sectional view of the semiconductor integrated circuit device shown in FIG. 1, taken on line II-II. For clarifying the distinctive feature of the present embodiment, some components may be different from the real ones in size and the like. Moreover, like or corresponding components are designated by the same reference numerals as the ones of the first embodiment.

In the semiconductor integrated circuit device 20 shown in FIGS. 5 and 6, a first interlayer insulating film 21 and a first metal layer M1; a second insulating film 22 and a second metal layer M2; a third insulating film 23 and a third metal layer M3; a fourth insulating film 24 and a fourth metal layer M4; a fifth insulating film 25 and a fifth metal layer M5; and a sixth insulating film 26 and a sixth metal layer M6 are subsequently formed on a semiconductor substrate 11 made of, e.g., silicon via an element separating area 11A which is formed at the surface area of the semiconductor substrate 11.

The first metal pattern M1 constitutes a wiring pattern, and the second metal layer M2 constitutes a dummy metal portion M2-1 and a wiring pattern M2-2. The third metal layer M3 constitutes a dummy metal portion M3-1 and a wiring pattern M3-2, and the third metal layer M4 constitutes a dummy metal portion M4-1 and a wiring pattern M4-2. The fifth metal layer M5 also constitutes a dummy metal portion M5-1 and a wiring pattern M5-2. The sixth metal layer M6 constitutes a metal fuse (functional element) which is defined as the narrow portion M6-1 positioned at the center thereof.

The first metal layer M1 is electrically connected with the wiring pattern M2-2 of the second metal layer M2 with an interlayer connector (via) 12. The wiring pattern M2-2 is electrically connected with the wiring pattern M3-2 of the third metal layer M3 with an interlayer connector (via) 13. The wiring pattern M3-2 is electrically connected with the wiring pattern M4-2 of the fourth metal layer M4 with an interlayer connector (via) 14. The wiring pattern M4-2 is electrically connected with the wiring pattern M5-2 of the fifth metal layer M5 with an interlayer connector (via) 15. The wiring pattern M5-2 is electrically connected with the sixth metal layer (metal fuse) M6 with an interlayer connector (via) 16.

In this embodiment, as viewed in the lateral direction of the semiconductor integrated circuit device 20 shown in FIGS. 5 and 6, the second metal layer M2 through the fifth metal layer M5 include the dummy metal portion M2-1 and M5-1 which are located inside the interlayer connectors 12 to 15 and outside the metal fuse M6-1. Then, as apparent from FIG. 5, the dummy metal portions M2-1 to M5-1 are made of a plurality of metal pieces so that the metal pieces enclose the metal fuse M6-1 and are arranged by the spacing “d”.

During the manufacture of the semiconductor integrated circuit device shown in FIGS. 5 and 6, therefore, even though the second interlayer insulating film 22 is formed after the first interlayer insulating film 21 and the first metal layer M1 are formed on the semiconductor substrate 11 and thermal treatment is conducted for the second interlayer insulating film 22 before the second metal layer M2 is formed, the gas components and moisture component remaining in the second interlayer insulating film 22 are concentrated on the trench (dummy trench) which is previously formed so as to form the dummy metal portion M2-1 and thus, emitted outside via the trench, not the trench (wiring trench) which is previously formed so as to form the wiring pattern M2-2.

As a result, the gas components and moisture component are not concentrated on the trench for forming the wiring pattern M2-2 so that the damage of the opening for forming the interlayer connector 12, the opening being continuous to the trench, can be suppressed and thus, the increase in resistance of the opening can be suppressed.

Moreover, even though thermal treatment is conducted for the third interlayer insulating film 23 before the third metal layer M3 is formed, the gas components and moisture component remaining in the third interlayer insulating film 23 are concentrated on the trench (dummy trench) which is previously formed so as to form the dummy metal portion M3-1 and thus, emitted outside via the trench, not the trench (wiring trench) which is previously formed so as to form the wiring pattern M3-2. In addition, even though thermal treatment is conducted for the fourth interlayer insulating film 24 before the fourth metal layer M4 is formed, the gas components and moisture component remaining in the fourth interlayer insulating film 24 are concentrated on the trench (dummy trench) which is previously formed so as to form the dummy metal portion M4-1 and thus, emitted outside via the trench, not the trench (wiring trench) which is previously formed so as to form the wiring pattern M4-2.

Even though the fifth interlayer insulating film 25 is formed and thermal treatment is conducted for the fifth interlayer insulating film 25 before the fifth metal layer M5 is formed, the gas components and moisture component remaining in the fifth interlayer insulating film 25 are concentrated on the trench (dummy trench) which is previously formed so as to form the dummy metal portion M5-1 and thus, emitted outside via the trench, not the trench (wiring trench) which is previously formed so as to form the wiring pattern M5-2.

As a result, the gas components and moisture component are not concentrated on the trenches for forming the wiring patterns M3-2 to M5-2 so that the damage of the openings for forming the interlayer connectors 13 to 15, the openings being continuous to the trenches, can be suppressed and thus, the increase in resistance of the openings can be suppressed.

Accordingly, the increase in resistance of the openings for forming the interlayer connectors 12 to 15 can be suppressed so that the deterioration of the electric characteristics of the semiconductor integrated circuit device 20 can be prevented.

Moreover, since the dummy metal portions M2-1 and M5-1 are formed so as to enclose the metal fuse M6-1, the stiffness of the interlayer insulating films 21 to 26 can be compensated with the dummy metal portions M2-1 to M5-1 even though the interlayer insulating films 21 to 26 are made of low dielectric material with low stiffness. As a result, the mechanical strength of the semiconductor integrated circuit device 20 can be maintained sufficiently in the use of the low dielectric material.

Moreover, since no metal layer is formed below the metal fuse M6-1, the laser beam is not attracted to the dummy metal patterns in the process of cutting the metal fuse M6-1 with the laser beam. Therefore, the blow margin can be obtained sufficiently so that the laser beam can be sufficiently irradiated onto the metal fuse and thus, the above-described cutting process can be performed sufficiently.

In this embodiment, the dummy metal portions M2-1 and M5-1 are made of the metal pieces as described above. In this case, the spacing “d” between the adjacent pieces is set three times or less as large as the minimum wiring spacing required for the semiconductor integrated circuit device. Preferably, the spacing “d” is set to the minimum wiring spacing or less. In this case, the gas components and moisture component remaining in the interlayer insulating films 21 and 25 are not captured in and thus, passed through the trenches for forming the dummy metal portions M2-1 to M6-1. Therefore, the gas components and moisture component are unlikely to be delivered to the trenches for forming the wiring patterns M2-2 to M5-2.

The minimum wiring spacing can be defined in the same manner as in the first embodiment. At present, the minimum wiring spacing is set to 0.1 μm. The metal layers M1 to M6 partially constitute the wiring pattern as described above. In this point of view, the metal layers M1 to M6 may be made of a conventional wiring pattern material such as Cu, Au, Ag, Al.

In the second embodiment, some modified embodiments can be established as in the first embodiment. For example, the dummy metal portions M2-1 to M5-1 may be made of continuous metal members, respectively.

Although the present invention was described in detail with reference to the above examples, this invention is not limited to the above disclosure and every kind of variation and modification may be made without departing from the scope of the present invention.

In the embodiments, for example, the number of the metal layer and the interlayer insulating film is set to six, but may be set any number depending on the characteristics and use required for the intended semiconductor integrated circuit device. Moreover, in the embodiments, the capacitance elements and metal fuse are employed as the functional elements. However, any functional element may be employed and the number of functional element may be set to any number depending on the use and the like of the semiconductor integrated circuit device.

What is claimed is:

1. A semiconductor integrated circuit device, comprising:
a plurality of metal wirings which are separated from one another with respective interlayer insulating films;
at least one interlayer conductor for electrically connecting adjacent ones of said metal wirings through the corresponding one of said interlayer insulating films;
at least one functional element formed above a semiconductor substrate and between adjacent ones of said interlayer insulating films; and
at least one dummy metal portion which is formed above and/or below said functional element at least one of said interlayer insulating films so as to be located inside said at least one interlayer conductor.

2. The device as set forth in claim 1,
wherein said at least one dummy metal portion is formed in a dummy trench which is previously formed in corresponding at least one of said interlayer insulating films.

3. The device as set forth in claim 2,
wherein said metal wirings are formed in wiring trenches which are previously formed in corresponding ones of said interlayer insulating films.

4. The device as set forth in claim 3,
wherein said at least one dummy metal portion is located above at least one of said metal wirings.

5. The device as set forth in claim 1,
wherein said at least one dummy metal portion is located outside said functional element so as not to be overlapped with said at least one functional element in a thickness direction of said semiconductor integrated circuit device.

6. The device as set forth in claim 1,
wherein said at least one functional element is configured so as not to be overlapped with said metal wirings and said at least one dummy metal portion in a thickness direction of said semiconductor integrated circuit device.

7. The device as set forth in claim 1,
wherein said at least one dummy metal portion is configured so as to enclose said at least one functional element.

8. The device as set forth in claim 1,
wherein said at least one dummy metal portion is made of continuous metal member.

9. The device as set forth in claim 1,
wherein said at least one dummy metal portion is made of a plurality of metal pieces.

10. The device as set forth in claim 9,
wherein a spacing between adjacent ones of said metal pieces is set three times or less as large as a minimum wiring spacing required for said semiconductor integrated circuit device.

11. The device as set forth in claim 1,
wherein said at least one functional element is a capacitance element.

12. The device as set forth in claim 1,
wherein said at least one functional element is a metal fuse.

13. A method for manufacturing a semiconductor integrated circuit device, comprising:
forming a first metal wiring above a semiconductor substrate;
forming a first interlayer insulating film on said first metal wiring;
forming a first trench and a second trench in said first interlayer insulating film so that said second trench is located outside said first trench;
forming a dummy metal portion in said first trench;
forming a second metal wiring in said second trench;
forming an interlayer conductor for electrically connecting said first metal wiring and said second metal wiring through said first interlayer insulating film;
forming a second interlayer insulating film on said first interlayer insulating film so as to cover said dummy metal portion and said second metal wiring; and
forming a functional element in said second interlayer insulating film.

14. The method as set forth in claim 13,
wherein said dummy metal portion is located outside said functional element so as not to be overlapped with said functional element in a thickness direction of said semiconductor integrated circuit device.

15. The method as set forth in claim 13,
wherein said functional element is formed so as not to be overlapped with said first metal wiring, said second metal wiring and dummy metal portion in a thickness direction of said semiconductor integrated circuit device.

16. The method as set forth in claim 13,
wherein said dummy metal portion is formed so as to enclose said functional element.

17. The method as set forth in claim 13,
wherein said dummy metal portion is made of continuous metal member.

18. The method as set forth in claim 13,
wherein said dummy metal portion is made of a plurality of metal pieces.

19. The method as set forth in claim 18,
wherein a spacing between adjacent ones of said metal pieces is set three times or less as large as a minimum wiring spacing required for said semiconductor integrated circuit device.

20. The method as set forth in claim 13,
wherein said first interlayer insulating film is thermally treated before said dummy metal portion and said second metal wiring are formed.
